(19) United States
(12) Patent Application Publication
(10) Pub. No.: US 2023/0274862 A1
(43) Pub. Date: Aug. 31, 2023

(54) Thin Film Resistance Element and High-Frequency Circuit

(71) Applicant: Nippon Telegraph and Telephone Corporation, Tokyo (JP)

(72) Inventors: Hiroshi Hamada, Tokyo (JP); Hideyuki Nosaka, Tokyo (JP)

(21) Appl. No.: 18/006,342

(22) PCT Filed: Aug. 3, 2020
(86) PCT No.: PCT/JP2020/029663

§ 371 Date: Jan. 20, 2023

(51) Int. Cl. H01C 7/00; H03H 7/24; H01C 1/14; H03F 3/195

(52) U.S. Cl. CPC H01C 7/006; H03H 7/24; H01C 1/14; H03F 3/195

(57) ABSTRACT

A thin-film resistive element includes: a first electrode that is formed with a conductor formed in an annular shape in a planar view; a second electrode that is formed with a conductor disposed at a distance from the first electrode in a region surrounded by the first electrode; and a thin-film resistor that is electrically connected to the first electrode and the second electrode.

### CROSS-REFERENCE TO RELATED APPLICATIONS

This application is a national phase entry of PCT Application No. PCT/JP2020/029663, filed on Aug. 3, 2020, which application is hereby incorporated herein by reference.

### TECHNICAL FIELD

The present invention relates to a circuit technology for handling radio-frequency electrical signals, and more particularly, to a thin-film resistive element and a high-frequency circuit.

### BACKGROUND

As one mode for achieving a resistance in an integrated circuit, a thin-film resistance is known (see Non Patent Literature 1, for example). A thin-film resistance is a resistive element that is formed by patterning a thin metal film. For example, as illustrated in FIGS. 8B and 8C, a thin-film resistive element that realizes a resistance as illustrated in FIG. 8A using a thin-film resistance includes a thin-film resistance 203 formed on a substrate 204 formed with ceramics or a semiconductor, and metal electrodes 201 and 202 formed on the thin-film resistance 203. In such a layout, the thin-film resistance 203 formed between the metal electrode 201 and the metal electrode 202 acts as a resistor, a series resistance is inserted between the metal electrodes 201 and 202 in the layout illustrated in FIGS. 8B and 8C. At this stage, the resistance value R generated between the electrodes is calculated according to Equation 1 shown below.

R=ρ×L/W (Equation 1)

In Equation 1, p represents the sheet resistivity of the thin-film resistance 203, L represents the length of the thin-film resistance 203 between the metal electrodes 201 and 202, and W represents the width of the thin-film resistance 203.

In the case of a compound semiconductor process, a typical p value is 100 to 200 [Ω·μm]. According to Equation 1, in the resistance layout of a thin-film resistive element 20H having a high resistance value, the length L is greater than the width W, as illustrated in FIG. 9A. In the resistance layout of a thin-film resistive element 20L having a low resistance value, the width W is greater than the length L, as illustrated in FIG. 9B.

Here, it is difficult to form the thin-film resistive element 20L having a low resistance value illustrated in FIG. 9B in a high-frequency band exceeding 100 GHz. The reason for that is now described with reference to FIG. 9C.

FIG. 9C is a diagram illustrating an equivalent circuit of the low-resistance thin-film resistive element 20L in a high-frequency band. In a high-frequency band, the width W of the electrodes 201 and 202 cannot be ignored with respect to the wavelength, and therefore, inductors, resistances, and capacitances are equivalently distributed in the width direction. Here, the respective distribution values are represented by Ld, Cd, and Rd. For convenience sake, the thin-film resistor between the electrodes 201 and 202 is divided into eight distributed resistances as illustrated in FIG. 9C, and the inductance to be felt when a radio-frequency electrical signal S_{RF} follows the path indicated by a bold line extending through the distributed resistance X1 (resistance value: Rd) located at the upper end of the thin-film resistive element 20L having a low resistance value in FIG. 9C is approximated in the manner described below.

The radio-frequency electrical signal S_{RF} starting from the electrode 201 in FIG. 9C passes through three and a half distributed inductors before arriving at the entrance of the distributed resistance X. Further, before reaching the electrode 202 through the distributed resistance X, the radio-frequency electrical signal also pass through three and a half inductors. Therefore, the radio-frequency electrical signal S_{RF} passes through a total of seven inductors, and the total inductance is expressed as 7Ld.

Likewise, a radio-frequency electrical signal passing through the distributed resistance X2 immediately below the distributed resistance X1 has a total inductance of 5Ld through five distributed inductors, and a radio-frequency electrical signal passing through the distributed resistance X3 located two resistances below the distributed resistance X1 has a total inductance of 3Ld through three distributed inductors.

Therefore, the low-resistance thin-film resistive element 20L having a resistance layout in which the width W is greater than the length L as illustrated in FIG. 9C can no longer be regarded as a resistance serving as a lumped parameter at a high frequency where the inductance in the width direction cannot be ignored, and becomes a resistance having a certain amount of parasitic inductance.

Of course, a similar effect also exists at a high resistance. For example, a resistive element having a high resistance value as illustrated in FIG. 9A is an element having a large amount of inductance in the length direction (L direction) of the resistance. However, this parasitic inductance is less likely to cause a problem, compared with a thin-film resistive element having a low resistance value. This is because a high resistance in a conventional high-frequency circuit is often used as a decoupling resistance (a typical resistance value being several kΩ) for applying bias to a transistor or the like. A thin-film resistive element having a high resistance value in this case has the purpose, which is “not to allow any radio-frequency signal to propagate in the length direction of the resistance”, and the parasitic inductance distributed in the length direction of the resistance acts in a direction that is advantageous in achieving this purpose.

In the case of a thin-film resistive element having a low resistance value, on the other hand, this inductance is a large problem. Normally, a low resistance of 20Ω or lower is used for an attenuator, an oscillation preventing circuit of an amplifying element, or the like. In this case, a more accurate resistance value is required compared with the case with a high resistance. However, when the impedance value of the resistance increases in a high-frequency band due to a parasitic inductor, the attenuator or the oscillation preventing circuit of the amplifying element stops operating as intended.

### CITATION LIST

### Non Patent Literature

Non Patent Literature 1: J. J. Bohrer, “Thin-Film Circuit Techniques,” IRE Trans. On Component Parts, Vol. 7, June 1960.

### SUMMARY

### Technical Problem

Embodiments of the present invention aim to reduce parasitic inductance of a thin-film resistive element in a high-frequency band.

### Solution to Problem

To achieve the above objective, a thin-film resistive element according to embodiments of the present invention includes: a first electrode (101) that is formed with a conductor formed in an annular shape in a planar view; a second electrode (102) that is formed with a conductor disposed at a distance from the first electrode in a region surrounded by the first electrode; and a thin-film resistor (103) that is electrically connected to the first electrode and the second electrode.

In a thin-film resistive element according to an embodiment of the present invention, the first electrode (1i) and the thin-film resistor (103) are each formed in a ring-like shape, the second electrode (102) is formed in a circular shape in a planar view, and the first electrode (101), the second electrode (102), and the thin-film resistor (103) are concentrically arranged.

In a thin-film resistive element according to an embodiment of the present invention, when the distance between the first electrode and the second electrode is represented by L, the circumferential length of the thin-film resistor in a ring-like shape is represented by W, and the sheet resistivity of the thin-film resistor is represented by ρ in the thin-film resistive element described above, the resistance value R is expressed as: R=ρ×L/W.

Further, a high-frequency circuit according to embodiments of the present invention is a high-frequency circuit including the thin-film resistive element described above.

A high-frequency circuit according to an embodiment of the present invention is a high-frequency amplifier that includes a transistor integrated on the substrate, and a bias supply line that supplies a bias to a terminal of the transistor, and the thin-film resistive element is inserted between the terminal of the transistor and the bias supply line.

A high-frequency circuit according to another embodiment of the present invention is a high-frequency attenuator formed with at least one resistive element formed on the substrate, and the at least one resistive element is the thin-film resistive element described above.

Advantageous Effects of Embodiments of the Invention

According to embodiments of the present invention, parasitic inductance of a thin-film resistive element in a high-frequency band can be reduced.

### BRIEF DESCRIPTION OF THE DRAWINGS

FIG. 1A is a plan view illustrating the layout of a thin-film resistive element according to a first embodiment of the present invention.

FIG. 1B is a plan view illustrating the layout of the relevant components of the thin-film resistive element according to the first embodiment of the present invention.

FIG. 1C is a cross-sectional view taken along the line IC-IC defined in FIG. 1A.

FIG. 2 is a diagram illustrating an equivalent circuit in a high-frequency band of the thin-film resistive element according to the first embodiment of the present invention.

FIG. 3 is a diagram illustrating an example configuration of a high-frequency amplifier having an oscillation preventing circuit.

FIG. 4A is a graph illustrating the frequency characteristics of the gain of a high-frequency amplifier including an oscillation preventing circuit using a thin-film resistive element according to a conventional technology.

FIG. 4B is a graph illustrating the frequency characteristics of the gain of the high-frequency amplifier including the oscillation preventing circuit using the thin-film resistive element according to the first embodiment of the present invention.

FIG. 5A is a graph illustrating the frequency characteristics of S parameters of a high-frequency amplifier including an oscillation preventing circuit using a thin-film resistive element according to a conventional technology.

FIG. 5B is a graph illustrating the frequency characteristics of S parameters of the high-frequency amplifier including the oscillation preventing circuit using the thin-film resistive element according to the first embodiment of the present invention.

FIG. 6A is a graph illustrating the frequency characteristics of the stability factor (K factor) of a high-frequency amplifier including an oscillation preventing circuit using a thin-film resistive element according to a conventional technology.

FIG. 6B is a graph illustrating the frequency characteristics of the stability factor (K factor) of the high-frequency amplifier including the oscillation preventing circuit using the thin-film resistive element according to the first embodiment of the present invention.

FIG. 7 is a diagram for explaining an example configuration of an attenuator according to a third embodiment of the present invention.

FIG. 8A is a circuit diagram illustrating a resistance.

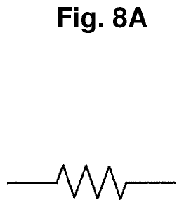

FIG. 8B is a plan view illustrating an example configuration of a thin-film resistive element.

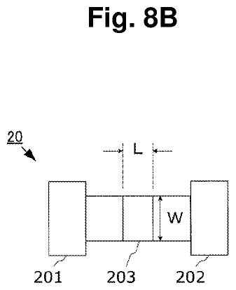

FIG. 8C is a cross-sectional view illustrating an example configuration of a thin-film resistive element.

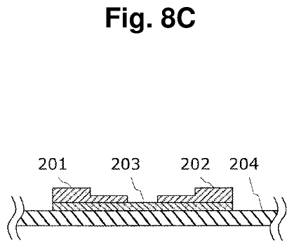

FIG. 9A is a plan view for explaining the layout of a thin-film resistive element having a high resistance value according to a conventional technology.

FIG. 9B is a plan view for explaining the layout of a thin-film resistive element having a low resistance value according to the conventional technology.

FIG. 9C is a diagram illustrating an equivalent circuit of the thin-film resistive element having a low resistance value in a high-frequency band according to the conventional technology.

### DETAILED DESCRIPTION OF ILLUSTRATIVE EMBODIMENTS

The following is a description of embodiments of the present invention, with reference to the drawings.

### First Embodiment

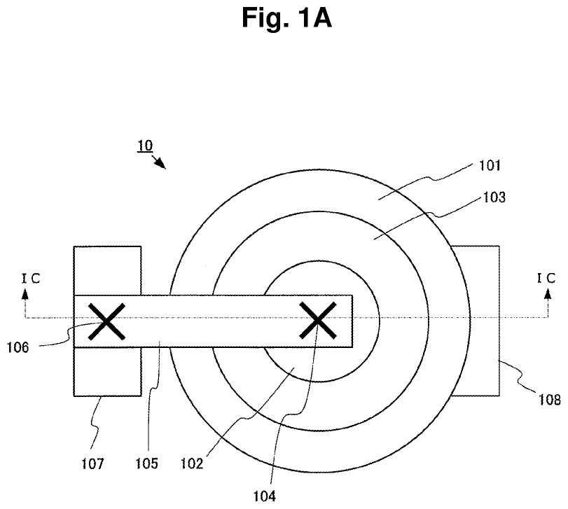

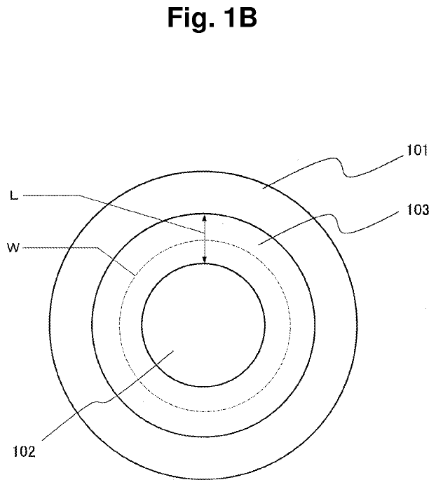

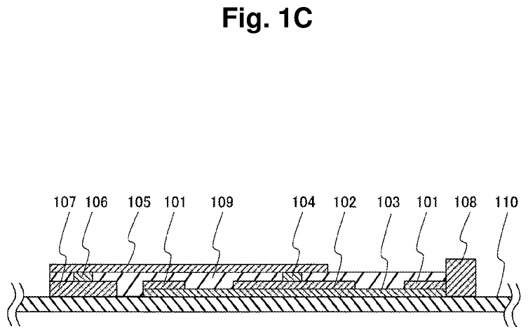

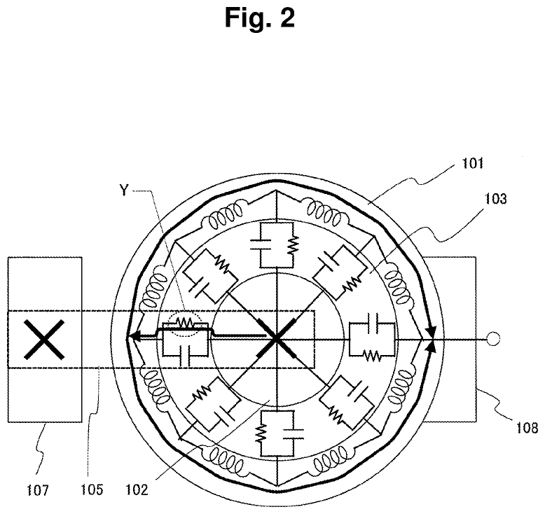

Referring to FIGS. 1A, 1B, 1C, and 2, the configuration and the principles of a thin-film resistive element according to a first embodiment of the present invention are now described.

FIG. 1A illustrates the layout of a thin-film resistive element according to this embodiment in a case where a low resistance is inserted between left and right metals (a third electrode 107 and a fourth electrode 108). FIG. 1B is a diagram illustrating a state in which a connection conductor 105 and the third electrode 107 illustrated in FIG. 1A are removed for ease of explanation.

Note that the connection conductor 105 is a member that electrically connects a second electrode 102 and the third electrode 107 of a thin-film resistive element 10 via contacts 104 and 106.

As illustrated in FIGS. 1A and 1B, the thin-film resistive element 10 according to the first embodiment of the present invention includes: a first electrode 101 that is formed with a conductor formed in an annular shape in a planar view; the second electrode 102 that is formed with a conductor disposed at a distance from the first electrode 101 in a region surrounded by the first electrode 101; and a thin-film resistor 103 that is electrically connected to the first electrode 101 and the second electrode 102.

More specifically, the first electrode 101 is formed in an annular shape, the second electrode 102 is formed in a circular shape, and these electrodes are arranged concentrically. In the thin-film resistive element 10 according to this embodiment, the thin-film resistor 103 is formed in a donut-like shape between the first electrode 101 and the second electrode 102 that are arranged concentrically.

In the thin-film resistive element 10 as described above, the thin-film resistor 103 having a circular shape in a planar view is formed on a substrate 110 formed with a dielectric material, and the first electrode 101 and the second electrode 102 are concentrically formed on the thin-film resistor 103, as illustrated in FIG. 1C. To connect the second electrode 102 to the third electrode 107 formed on the substrate 110, an insulating film 109 covering the first electrode 101, the thin-film resistor 103, and the third electrode 107 is formed, for example, and contacts 104 and 106 are formed in through holes formed in the insulating film 109.

Here, the distance between the first electrode 101 and the second electrode 102 is represented by L, and the length of the line (indicated by a dot-and-dash line in FIG. 1B) that connects points equidistant from the first electrode 101 and the second electrode 102 is defined as the circumferential length W of the thin-film resistor 103. In this case, an electrical signal concentrically propagates in the thin-film resistor 103. Accordingly, the length of the thin-film resistor 103 corresponds to the length L that is the signal propagation length illustrated in FIG. 1B, and the physical quantity corresponding to the width of the thin-film resistor 103 corresponds to the circumferential length W of the donut-shaped thin-film resistor 103. Like a general resistance, the resistance value of the thin-film resistive element 10 at this point of time can be calculated using the above-mentioned Equation 1 using L and W as parameters.

Note that, since the first electrode 101 and the second electrode 102 are concentrically arranged, the circumferential length W equivalently increases as a signal propagates. However, the length L between the electrodes is small with a low resistance, and therefore, the influence of this can be substantially ignored.

Next, the principles of embodiments of the present invention, or the reason why the parasitic inductance is reduced by the thin-film resistive element according to this embodiment is explained through the configuration illustrated in FIGS. 1A and 1B.

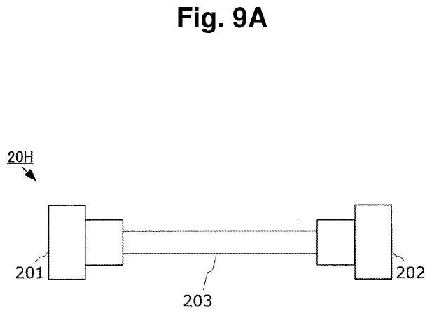

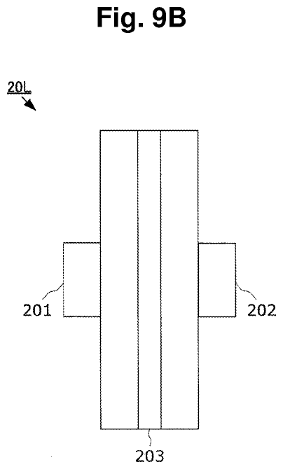

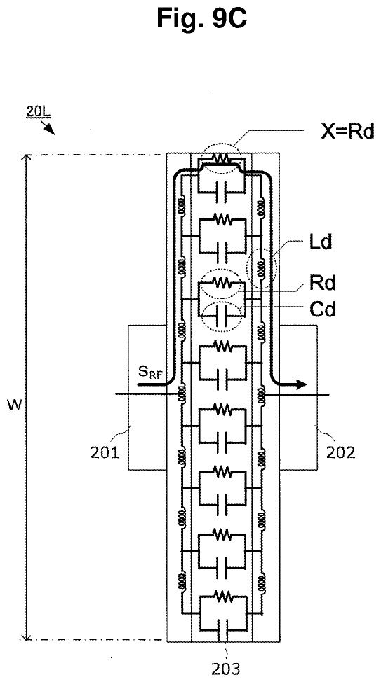

As described above, in a high-frequency band, the thin-film resistive element 20L according to the conventional technology in which the thin-film resistance 203 is disposed between the two electrodes 201 and 202 extending substantially parallel to each other as illustrated in FIGS. 9B and 9C hardly achieves a low resistance with the inductors distributed in the width direction of the thin-film resistive element 20L. On the other hand, the thin-film resistive element according to this embodiment is designed to reduce the parasitic inductors by having a circular layout.

FIG. 2 illustrates an equivalent circuit of the thin-film resistive element 10 illustrated in FIG. 1A in a high-frequency band. In FIG. 2, for a valid comparison with the thin-film resistive element 20 illustrated in FIG. 9C, the thin-film resistor 103 between the first electrode 101 and the second electrode 102 is also divided into eight distributed resistances in a circumferential direction, to approximate the inductance to be felt by a radio-frequency electrical signal.

Here, the distributed resistance having the largest total amount of parasitic inductance is the distributed resistance Y farthest from the metal (the fourth electrode 108) on the right side in FIG. 2. There are two paths for an electrical signal passing through the distributed resistance Y to reach the fourth electrode 108, which are an upper half and a lower half of the circumference of the annular first electrode 101 as indicated by a bold line in FIG. 2.

Therefore, where the distributed inductance value is Ld as in FIG. 9C, the parasitic inductance of the upper half path is 4Ld, and the parasitic inductance of the lower half path is also 4Ld. Since these two paths are inserted in parallel between the distributed resistance Y and the fourth electrode 108, the total inductance value is 2Ld, which is half the parasitic inductance of each path.

Likewise, when viewed from the resistance to the right of the distributed resistance Y, the parasitic inductance of the path on the upper side of the circumference of the first electrode 101 is 3Ld, and the parasitic inductance of the path on the lower side is 5Ld. Accordingly, the combined parasitic inductance value is about 1.9Ld. Also, as for the resistance to the right of the above resistance, the parasitic inductance of the path on the upper side of the circumference is 2Ld, and the parasitic inductance of the path on the lower side is 6Ld. Accordingly, the combined parasitic inductance value is about 1.5Ld. Further, as for the resistance to the right of the above resistance, the parasitic inductance of the path on the upper side of the circumference is Ld, and the parasitic inductance of the path on the lower side is 7Ld. Accordingly, the combined parasitic inductance value is about 0.9Ld. All of these parasitic inductance amounts are lower than the value of the parasitic inductance amount of the thin-film resistive element according to the conventional technology illustrated in FIG. 9C. As a result, the parasitic inductance amount of the thin-film resistive element 10 according to this embodiment can be made smaller than that with the conventional layout.

In the thin-film resistive element 10 according to this embodiment, the thin-film resistor 103 described above can be formed by patterning a resistor layer formed on the substrate 110 formed with an insulator such as ceramics, or a semiconductor or the like, for example. The material of the resistor may be a metal material such as titanium or a nickel chrome alloy, for example. Further, the first electrode 101 and the second electrode 102, and the third electrode 107 and the fourth electrode 108 are formed on the above-described thin-film resistor 103 and the substrate, respectively. The material forming these electrodes may be a material having a higher conductivity than that of the material forming the thin-film resistor 103, such as gold. These electrodes may be selectively formed in predetermined regions by a technique related to thin-film formation, such as sputtering or etching. Further, an insulating layer may be formed between the first electrode 101 and the connection conductor 105.

Note that, in this embodiment, the first electrode 101 and the second electrode 102 are formed in a circular shape in a planar view. However, it is sufficient that the first electrode 101 is formed in an annular shape, and the second electrode 102 is disposed in a region inside the annular shape. The planar shape of these electrodes may be a circular shape or a polygonal shape close to a circular shape.

### Second Embodiment

Next, a high-frequency amplifier in which the thin-film resistive element 10 according to the first embodiment described above is applied to an oscillation preventing circuit is described as a second embodiment of the present invention.

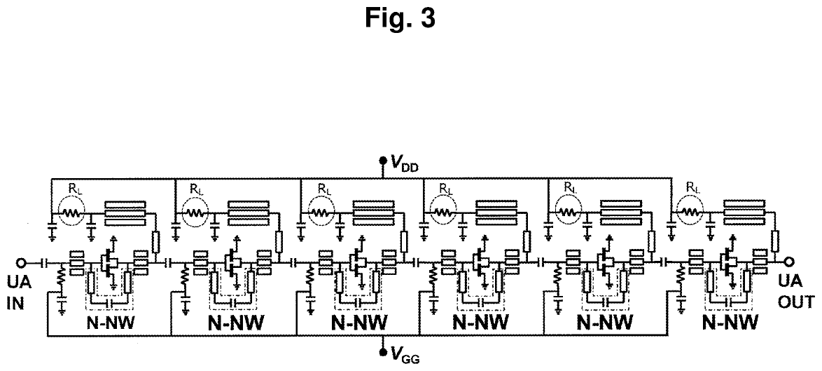

FIG. 3 illustrates an example of a 500 GHz band amplifier. This amplifier is a circuit using neutralizing circuits N-NW for maximizing the gain of the amplifier (source grounded) to obtain a gain in a significantly high frequency band of 500 GHz. An input/output of a transistor that is an amplifier is connected to such a neutralizing circuit N-NW. Therefore, there is a frequency at which an output signal of the transistor is input to the transistor in the same phase as the input signal in a frequency band other than the 500 GHz band that is an operating frequency, and oscillation (out-of-band oscillation) might occur at such a frequency in some cases. A low resistance is required for the oscillation preventing circuit that is used to prevent such out-of-band oscillation.

That is, in this embodiment, a low resistance R_{L} of about 10Ω is inserted as the oscillation preventing circuit between the line that supplies bias to the drain of the transistor and the drain of the transistor. When the value of the low resistance R_{L} is appropriately selected, an out-of-band signal can be absorbed by this resistance, and a loss can be caused in the out-of-band signal. Thus, out-of-band oscillation can be prevented.

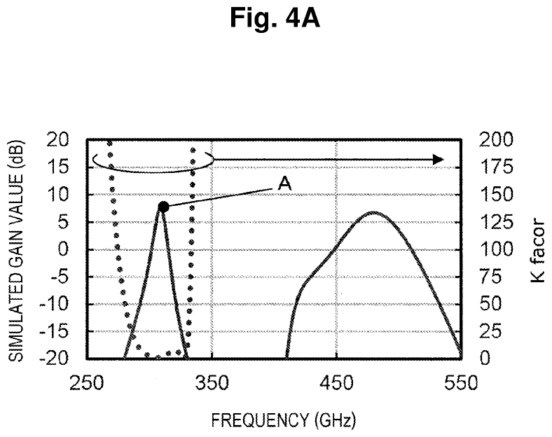

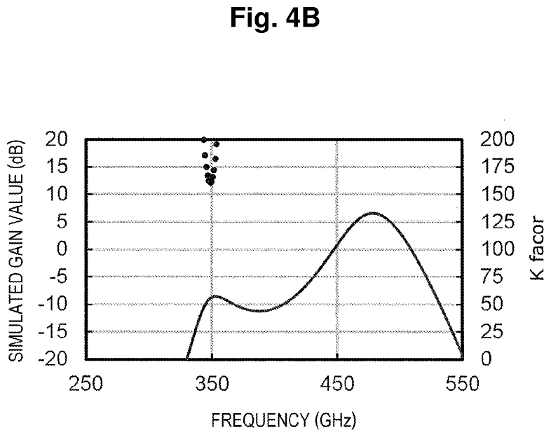

Regarding the high-frequency amplifier illustrated in FIG. 3, FIG. 4A illustrates a gain result and a stability index calculation result in a case where the low resistance R_{L} is 0Ω, which is a case where the portion of the low resistance R_{L} is connected by a normal transmission line. Also, FIG. 4B illustrates a gain result and a stability index calculation result in a case where the value of the low resistance R_{L} acting as the oscillation preventing circuit is 10Ω. Note that, in this calculation, the resistance is regarded as an ideal resistance of 10Ω without any parasitic inductor.

The designed operating frequency of this high-frequency amplifier is 480 GHz, and, as can be seen from solid lines in FIGS. 4A and 4B, a gain of about 7 dB is obtained in the vicinity of 480 GHz in both cases with and without a resistance of 10Ω. In a case where there is no resistance of 10Ω, a large out-of-band gain (A) is generated even in the vicinity of 300 GHz, as illustrated in FIG. 4A. Also, around 300 GHz, the stability index (K factor) indicated by a dotted line is 1 or less, which indicates that out-of-band oscillation has occurred.

On the other hand, in a case where a resistance of 10Ω is used, the out-of-band gain is reduced, and the stability index is significantly increased, as illustrated in FIG. 4B.

The test results described next concern the influence of the parasitic inductance of the low resistance R_{L} of the oscillation preventing circuit in each of the cases where the very low resistance of 10Ω was achieved by the conventional technology with the layout as illustrated in FIG. 9B, and where the very low resistance is achieved by the thin-film resistive element 10 according to the first embodiment.

A resistor having a low resistivity that is a sheet resistivity ρ=150Ω·μm was used as the thin-film resistor. Further, in the layout of the thin-film resistive element according to the conventional technology illustrated in FIG. 9B, W=30 μm, and L=2 μm. Note that, to reduce the parasitic inductors, the width W is reduced, but the length L also needs to be reduced at the same time in this case. However, L cannot be reduced infinitely because of the process rules. The value of the length L=2 μm is the typical minimum value that can be achieved by a general compound semiconductor process. On the other hand, in the layout of the thin-film resistive element according to the first embodiment as illustrated in FIGS. 1A and 1B, the circumferential length W=30 μm, and the length L=2 μm.

To test the effects of the two different layouts, the S parameters of these two resistances were subjected to electromagnetic analysis, and the results were inserted into the portion of the low resistance R_{L} in FIG. 3, to test the effects of the parasitic layouts.

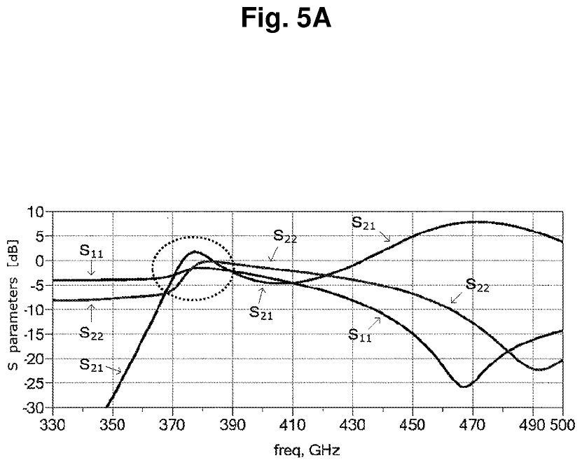

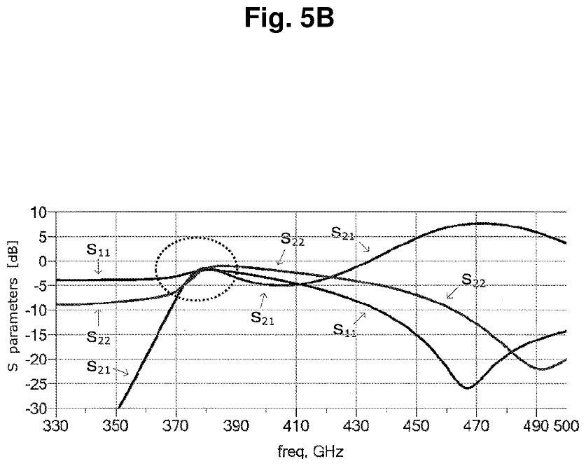

First, FIG. 5A illustrates the results of calculation of the S parameters in a case where a resistance according to the conventional technology as illustrated in FIG. 9B was used. Comparing FIG. 5A with FIG. 4A, the significant out-of-band gain (A) around 300 GHz seen in FIG. 4A is not seen in FIG. 5A. It is safe to say that this is an effect of the 10Ω resistance. However, another out-of-band gain occurred at 380 GHz, which is a higher frequency. Further, according to FIG. 5A, it can be seen that an out-of-band gain exists in the vicinity of 380 GHz, and an output return (S22) exceeds 0 dB. This indicates typical oscillation. This is considered to be a result of the parasitic inductance that is not taken into consideration in the high-frequency amplifier illustrated in FIG. 3 but was inserted into the circuit due to the inductance parasitic on the 10Ω resistance, and the slight inductance that caused resonance with the capacitance in the circuit. In a frequency band exceeding 300 GHz, both the capacitance and the inductance used in the circuit are very low, and therefore, such oscillation is caused by a small amount of parasitic inductors included in the 10Ω resistance.

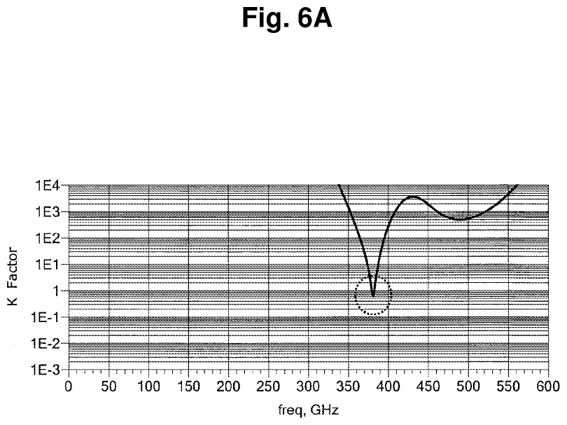

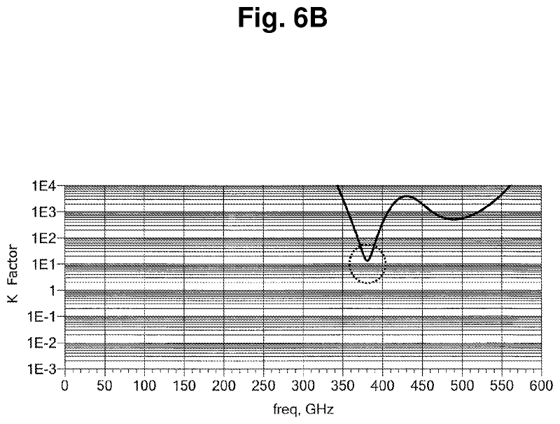

FIG. 6A illustrates the results of calculation of the stability index of a high-frequency amplifier using a resistance according to the conventional technology for such an oscillation preventing circuit. It can be seen that, around the frequency of 380 GHz at which an out-of-band gain occurred in FIG. 5A, the stability index (K factor) is 1 or less, and the amplifier is in an unstable state.

On the other hand, FIGS. 5B and 6B each illustrate the results of calculation of the S parameters and the stability index (K factor) in a case where the low resistance R_{L} of the oscillation preventing circuit is achieved with the thin-film resistive element 10 according to the first embodiment. According to FIG. 5B, the out-of-band gain in the vicinity of 380 GHz is greatly reduced, and the reflection characteristics (S22) do not exceed 0 dB. Further, as illustrated in FIG. 6B, the stability index (K factor) is also greatly increased to a great value of 10 or higher.

As the thin-film resistive element 10 according to this embodiment has the effect to reduce parasitic inductance as described above, the 10Ω resistance can appear to be a purer resistance even in such a high-frequency band. Accordingly, a great effect is achieved to prevent the oscillation that is shown in FIGS. 5A and 6A and is difficult to be predicted by the thin-film resistive element according to the conventional technology.

### Third Embodiment

Next, an attenuator using the thin-film resistive element 10 according to the first embodiment described above is described as a third embodiment of the present invention.

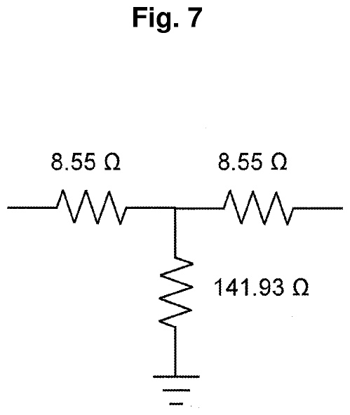

In a case where an integrated attenuator with a small attenuation amount in a high-frequency band is to be formed, it is necessary to use a low resistance. FIG. 7 is a diagram illustrating an example configuration of a 3 dB attenuator in a 50Ω system. As the attenuation amount becomes smaller, the value of the resistance being used also becomes smaller. In a case where such an attenuator is formed in a high-frequency band, since the parasitic inductance is large in the layout of the thin-film resistive element according to the conventional technology as described above, there is a possibility that unintended oscillation will be caused in a circuit using the attenuator, for example, between stages of amplifiers.

On the other hand, in the attenuator according to this embodiment illustrated in FIG. 7, a resistance of 8.55Ω is formed with the thin-film resistive element according to the first embodiment described above. Thus, generation of low-resistance parasitic inductance can be reduced, and problems such as unintended oscillation in a high-frequency band can be avoided.

Although embodiments of the present invention have been described above, the present invention is not necessarily limited to these embodiments. Various modifications that can be understood by those skilled in the art can be made to specific configurations and details of the present invention, within the scope of the present invention.

### INDUSTRIAL APPLICABILITY

The present invention can be used in the fields of circuit elements and high-frequency circuits that are used in high-frequency bands.

### REFERENCE SIGNS LIST

10 thin-film resistive element
101 first electrode
102 second electrode
103 thin-film resistor.

1-6. (canceled)

7. A thin-film resistive element comprising:
a first electrode comprising a conductor having an annular shape in a planar view;
a second electrode comprising a conductor disposed at a distance from the first electrode in a region surrounded by the first electrode; and
a thin-film resistor that is electrically connected to the first electrode and the second electrode.

8. The thin-film resistive element according to claim 7, wherein:
the thin-film resistor has an annular shape in the planar view;
the second electrode has a circular shape in the planar view; and
the first electrode, the second electrode, and the thin-film resistor are concentrically arranged.

9. The thin-film resistive element according to claim 7, wherein:
when a distance between the first electrode and the second electrode is represented by L, a circumferential length of the thin-film resistor in an annular shape is represented by W, and sheet resistivity of the thin-film resistor is represented by ρ, a resistance value R of the thin-film resistive element satisfies:
R=ρ×L/W.

10. A device comprising:
a substrate;
a high-frequency circuit on the substrate, the high-frequency circuit comprising a thin-film resistive element, wherein the thin-film resistive element comprises:
a first electrode comprising a conductor having an annular shape in a planar view;
a second electrode comprising a conductor disposed at a distance from the first electrode in a region surrounded by the first electrode; and
a thin-film resistor that is electrically connected to the first electrode and the second electrode.

11. The device according to claim 10, wherein:
the thin-film resistor has an annular shape in the planar view;
the second electrode has a circular shape in the planar view; and
the first electrode, the second electrode, and the thin-film resistor are concentrically arranged.

12. The device according to claim 10, wherein:
when a distance between the first electrode and the second electrode is represented by L, a circumferential length of the thin-film resistor in an annular shape is represented by W, and sheet resistivity of the thin-film resistor is represented by ρ, a resistance value R of the thin-film resistive element satisfies:
R=ρ×L/W.

13. The device according to claim 10, wherein:
the high-frequency circuit is a high-frequency amplifier that includes a transistor integrated on the substrate, and a bias supply line that supplies a bias to a terminal of the transistor; and
the thin-film resistive element is disposed between the terminal of the transistor and the bias supply line.

14. The device according to claim 10, wherein:
the high-frequency circuit is a high-frequency attenuator comprising the thin-film resistive element.

15. A thin-film resistive element comprising:
a first electrode comprising a conductor having a ring-like shape in a planar view;
a second electrode comprising a conductor spaced apart and surrounded by the first electrode; and
a thin-film resistor that is electrically connected to the first electrode and the second electrode.

16. The thin-film resistive element according to claim 15, wherein:
the thin-film resistor has an ring-like shape in the planar view;
the second electrode has a round shape in the planar view; and
the first electrode, the second electrode, and the thin-film resistor are concentrically arranged.

17. The thin-film resistive element according to claim 15, wherein:
when a distance between the first electrode and the second electrode is represented by L, a circumferential length of the thin-film resistor in an ring-like shape is represented by W, and sheet resistivity of the thin-film resistor is represented by ρ, a resistance value R of the thin-film resistive element satisfies:
R=ρ×L/W.
